(19) United States
(12) Patent Application Publication
(10) Pub. No.: US 2013/0224399 A1
(43) Pub. Date: Aug. 29, 2013

(54) METHOD OF FORMING NITROGEN-FREE DIELECTRIC ANTI-REFLECTION LAYER

(71) Applicant: SHANGHAI HUALI MICROELECTRONICS CORPORATION, (US)

(72) Inventors: ChienWei CHEN, Shanghai (CN); HsuSheng CHANG, Shanghai (CN)

(73) Assignee: SHANGHAI HUALI MICROELECTRONICS CORPORATION, Shanghai (CN)

(21) Appl. No.: 13/721,062

(22) Filed: Dec. 20, 2012

(30) Foreign Application Priority Data
Feb. 28, 2012 (CN) 201210050770.8

(51) Int. Cl. C23C 16/50

(52) U.S. Cl. CPC C23C 16/50
USPC 427/578; 427/569

(57) ABSTRACT

The present invention provides a method of forming a nitrogen-free dielectric anti-reflection layer comprising: introducing a reaction gas into the discharge tube until the reaction gas reaching a stable state; introducing the reaction gas into the reaction chamber and then generating a plasma, or generating a plasma and then introducing the reaction gas into the reaction chamber, wherein the time delay occurs between the two processes is utilized to perform the deposition of the nitrogen-free dielectric anti-reflection layer; finally stop introducing the reaction gas and then stop generating the plasma. The method can flexibly control the extinction coefficient and the refractive index of the nitrogen-free dielectric anti-reflection layer so as to obtain a straight photoresist pattern and greatly reduce the photoresist standing waves effect and photoresist poisoning effect.

### CROSS-REFERENCE TO RELATED APPLICATION

This application claims the priority benefit of China application serial no. 201210050770.8, filed Feb. 28, 2012. All disclosure of the China application is incorporated herein by reference.

### FIELD OF THE INVENTION

The present invention relates to the field of semiconductor manufacturing technology, and particularly to a method of forming a nitrogen-free dielectric anti-reflection layer.

### BACKGROUND OF THE INVENTION

Conventionally, nitrogen-free dielectric anti-reflection layers are formed by introducing plasma and reaction gas simultaneously. Referring to FIG. 1, a conventional process of forming a nitrogen-free dielectric anti-reflection layer comprises the following steps: Step S101, providing a reaction gas and introducing the reaction gas into the discharge tube until the reaction gas reaching a stable state; Step S102, introducing the reaction gas into the reaction chamber and generating a plasma simultaneously; Step S103, performing the deposition of the nitrogen-free dielectric anti-reflection layer, wherein, no time delay occurs between the process of introducing the reaction gas and generating the plasma; Step S104, stop introducing the reaction gas and then stop generating the plasma.

The thickness of the deposited nitrogen-free dielectric ARC layer is approximate hundreds angstroms, such as 200 to 500 angstroms and the whole deposition process takes only about 10 seconds. If the process of introducing the reaction gas and generating a plasma are performed at the same time with no time delay, it is difficult to control the refractive index and the extinction coefficient of the nitrogen-free dielectric anti-reflection layer, which may cause the poor photoresist shape, and thus the photoresist standing waves effect and photoresist poisoning effect cannot be eliminated effectively.

### SUMMARY OF THE INVENTION

Accordingly, at least one objective of the present invention is to provide a method of forming a nitrogen-free dielectric anti-reflection layer to control the extinction coefficient and the refractive index of the nitrogen-free dielectric anti-reflection layer, obtain a straight photoresist shape and significantly reduce the photoresist standing waves effect and photoresist poisoning effect.

To achieve these and other advantages and in accordance with the objective of the invention, as embodied and broadly described herein, the invention provides a method of forming a nitrogen-free dielectric anti-reflection layer comprising:

introducing a reaction gas into the discharge tube until the reaction gas reaching a stable state;

introducing the reaction gas into the reaction chamber and generating a plasma, wherein there is a time delay between the process of introducing the reaction gas and generating the plasma;

performing the deposition of a nitrogen-free dielectric anti-reflection layer; stop introducing the reaction gas;

stop generating the plasma.

According to the embodiment of the present invention, the reaction gas comprises silane, carbon dioxide and helium.

According to the embodiment of the present invention, the flow rate of the silane is 120 to 220 sccm, the flow rate of the carbon dioxide is 3800 to 5800 sccm, and the flow rate of the helium is 3800 to 5800 sccm.

According to the embodiment of the present invention, the time delay between the process of introducing the reaction gas and generating the plasma is in the range of 0.1 to 2 seconds.

According to the embodiment of the present invention, the process of introducing the reaction gas is performed prior to the process of generating the plasma.

According to still another illustrative embodiment of the present invention, the process of generating the plasma is performed prior to the process of introducing the reaction gas.

According to the embodiment of the present invention, the deposited thickness of the nitrogen-free anti-reflection layer is in the range of 200 Å to 500 Å, the reaction temperature is 400 degree Celsius, the pressure in the reaction chamber is in the range of 3.0 Torr to 4.0 Torr, the high RF power is in the range of 300W to 400W, the deposition time is in the range of 8 to 20 seconds.

According to the method of forming a nitrogen-free dielectric anti-reflection layer, when the process of introducing the reaction gas is performed prior to the process of generating the plasma, the content of silicon in the whole reaction chamber increases at the early stage so as to enhance the extinction coefficient and the refractive index of the nitrogen-free dielectric anti-reflection layer effectively. On the other hand, when the process of introducing the reaction gas is performed after the process of generating the plasma, the content of silicon in the whole reaction chamber decreases at the early stage so as to reduce the extinction coefficient and the refractive index of the nitrogen-free dielectric anti-reflection layer effectively. Therefore, the extinction coefficient and the refractive index of the nitrogen-free dielectric anti-reflection layer can be controlled by adjusting the time delay between the process of introducing the reaction gas and the process of generating the plasma, which is beneficial to obtain a straight photoresist shape and eliminate the photoresist standing waves effect and photoresist poisoning effect.

### BRIEF DESCRIPTION OF THE DRAWINGS

The method of forming a nitrogen-free dielectric anti-reflection layer of the present invention will be elucidated by reference to the following embodiments and the accompanying drawings, in which:

FIG. 1 is a flow chart showing a conventional method of forming a nitrogen-free dielectric anti-reflection layer;

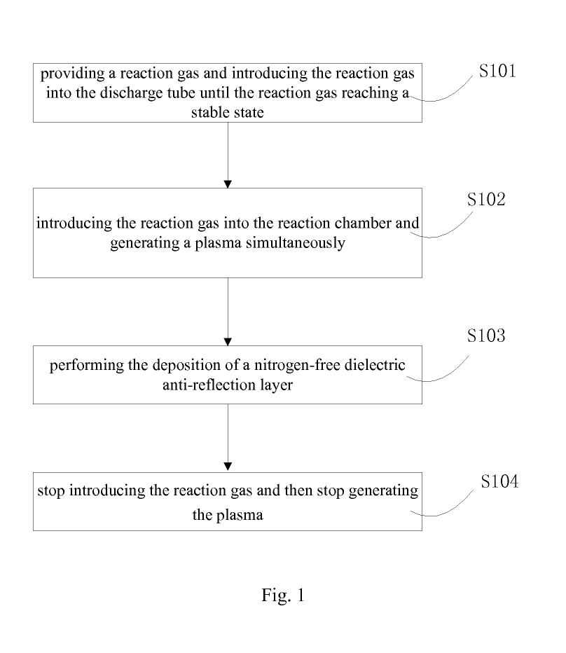

FIG. 2 is a flow chart showing the method of forming a nitrogen-free dielectric anti-reflection layer in one embodiment of the present invention.

### DETAILED DESCRIPTION OF THE EMBODIMENTS

A method of forming a nitrogen-free dielectric anti-reflection layer will be described in further details hereinafter with respect to the embodiment of the present invention and the accompanying drawings.

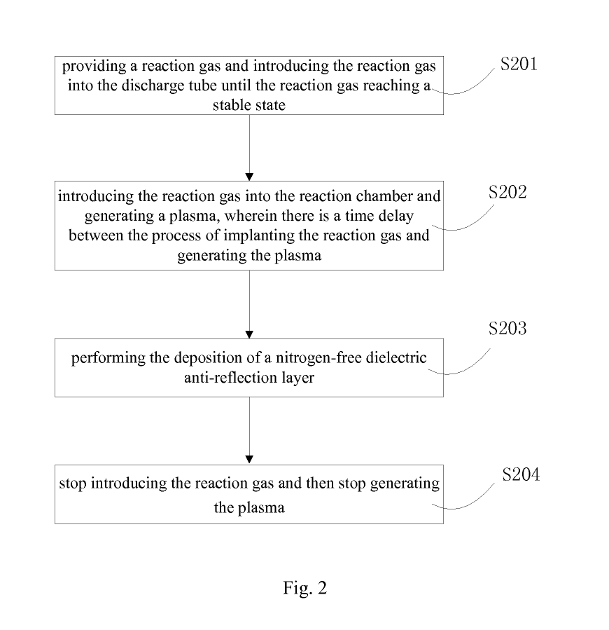

Referring to FIG. 2, a method of forming a nitrogen-free dielectric anti-reflection layer in the embodiment comprises the following steps:

Step S201, first providing a reaction gas, wherein the reaction gas can be a mixed gas of silane and carbon dioxide accompanied by some auxiliary gases such as helium or other inert gases. Then, introducing the reaction gas into a discharge tube until the reaction gas reaching a stable state; the flow rate of the reaction gas maintains stable.

Step S202, introducing the reaction gas into the reaction chamber and generating a plasma. There is a time delay between the process of introducing gas and the process of generating the plasma. Preferably, the time delay is in the range of 0.1 to 2 seconds. When the process of introducing the reaction gas is performed prior to the process of generating the plasma, the content of silicon in the whole reaction chamber will increase at the early stage so as to enhance the extinction coefficient and the refractive index of the nitrogen-free dielectric anti-reflection layer effectively. On the other hand, when the process of introducing the reaction gas is performed after the process of generating the plasma, the content of silicon in the whole reaction chamber will decrease at the early stage so as to reduce the extinction coefficient and the refractive index of the nitrogen-free dielectric anti-reflection layer effectively. Thus, the extinction coefficient and the refractive index can be flexibly controlled;

Step S203, performing the deposition of the nitrogen-free dielectric anti-reflection layer;

Step S204, stop introducing the reaction gas first and then stop generating the plasma.

In the embodiment of the present invention, the process temperature during the deposition of the nitrogen-free dielectric anti-reflection layer is approximately 400° C. The flow rate of the silane is 120 sccm to 220 sccm, the flow rate of the carbon dioxide is 3800 sccm to 5800 sccm and the flow rate of the helium is 3800 sccm to 5800 sccm. The pressure in the reaction chamber is in the range of 3.0 Torr to 4.0 Torr. The high RF power is in the range of 300W to 400W. The deposition time is in the range of 8 to 20 seconds. The thickness of the deposited nitrogen-free anti-reflection layer is in the range of 200 Å to 500 Å. The time delay between the process of introducing the reaction gas and generating the plasma is 0.1-2 seconds. The refractive index of the deposited nitrogen-free anti-reflection layer is in the range of 1.9 to 2.2 and the extinction coefficient is in the range of approximate 0.45 to 0.75.

Although the present invention has been disclosed as above with respect to the preferred embodiments, they should not be construed as limitations to the present invention. Various modifications and variations can be made by the ordinary skilled in the art without departing the spirit and scope of the present invention. Therefore, the protection scope of the present invention should be defined by the appended claims.

1. A method of forming a nitrogen-free dielectric anti-reflection layer comprising:
introducing a reaction gas into the discharge tube until the reaction gas reaching a stable state;
introducing the reaction gas into the reaction chamber and generating a plasma, wherein there is a time delay between the process of implanting the reaction gas and generating the plasma;
performing the deposition of a nitrogen-free dielectric anti-reflection layer;
stop introducing the reaction gas; and
stop generating the plasma.

2. The method according to claim 1, wherein the reaction gas comprises silane, carbon dioxide and helium.

3. The method according to claim 2, wherein the flow rate of the silane is 120 sccm to 220 sccm, the flow rate of the carbon dioxide is 3800 sccm to 5800 sccm, and the flow rate of the helium is 3800 sccm to 5800 sccm.

4. The method according to claim 1, wherein the time delay between the process of introducing the reaction gas and generating the plasma is in the range of 0.1 to 2 seconds.

5. The method according to claim 1, wherein the process of introducing the reaction gas is performed prior to the process of generating the plasma.

6. The method according to claim 1, wherein the process of generating the plasma is performed prior to the process of introducing the reaction gas.

7. The method according to claim 1, wherein the deposited thickness of the nitrogen-free dielectric anti-reflection layer is in the range of 200 Å to 500 Å; and during the deposition of the nitrogen-free dielectric anti-reflection layer, the reaction temperature is 400 degree Celsius, the pressure in the reaction chamber is in the range of 3.0 Torr to 4.0 Torr, the high RF power is in the range of 300W to 400 W, the deposition time is in the range of 8 to 20 seconds.
